(19) United States
(12) Patent Application Publication
(10) Pub. No.: US 2016/0260741 A1
(43) Pub. Date: Sep. 8, 2016

(54) SEMICONDUCTOR DEVICES HAVING FINS, AND METHODS OF FORMING SEMICONDUCTOR DEVICES HAVING FINS

(71) Applicants: STMicroelectronics, Inc., Coppell, TX (US); International Business Machines Corporation, Armonk, NY (US); GlobalFoundries Inc, Grand Cayman (KY)

(72) Inventors: Qing Liu, Irvine, CA (US); Chun-Chen Yeh, Clifton Park, NY (US); Ruilong Xie, Schenectady, NY (US); Xiuyu Cai, Niskayuna, NY (US); Kejia Wang, Poughkeepsie, NY (US)

(73) Assignees: STMicroelectronics, Inc., Coppell, TX (US); International Business Machines Corporation, Armonk, NY (US); GlobalFoundries Inc, Grand Cayman (KY)

(21) Appl. No.: 15/155,904

(22) Filed: May 16, 2016

Related U.S. Application Data
(62) Division of application No. 14/308,014, filed on Jun. 18, 2014.

(51) Int. Cl. H01L 27/12; H01L 27/088; H01L 21/311; H01L 29/78; H01L 29/66; H01L 21/02

(52) U.S. Cl. CPC H01L 27/1211; H01L 29/66795; H01L 21/0217; H01L 21/02247; H01L 21/31111; H01L 29/66545; H01L 29/785; H01L 27/0886

(57) ABSTRACT

In forming a finFET, a selective nitridation process is used during spacer formation on the gate to support a finer fin pitch than could be achieved using traditional spacer deposition processes. The spacer formation may also allow precise control over formation of source and drain junctions.

### CROSS-REFERENCE TO RELATED APPLICATION

This application is a divisional application from U.S. application for patent Ser. No. 14/308,014 filed Jun. 18, 2014 (now abandoned), the disclosure of which is incorporated by reference.

### TECHNICAL FIELD

The present disclosure relates to methods of forming semiconductor devices having one or more fin structures (“fins”), and to semiconductor devices having one or more fins. Some embodiments described in the present disclosure relate to finFETs and/or to methods for fabricating finFETs.

### BACKGROUND

Transistors are fundamental device elements of many modern digital processors and memory devices, and have found numerous applications in various areas of electronics including data processing, data storage, and high-power applications. Currently, there are a variety of transistor types and designs that may be used for different applications. Various transistor types include, for example, bipolar junction transistors (BJT), junction field-effect transistors (JFET), metal-oxide-semiconductor field-effect transistors (MOSFET), vertical channel or trench field-effect transistors, and superjunction or multi-drain transistors.

Two types of transistors which have emerged within the MOSFET family of transistors show promise for scaling to ultra-high density and nanometer-scale channel lengths. One of these transistor types is a so-called fin field-effect transistor or “finFET.” The channel of a finFET is formed in a three-dimensional fin that may extend from a surface of a substrate. FinFETs have favorable electrostatic properties for complimentary MOS (CMOS) scaling to smaller sizes. Because the fin is a three-dimensional structure, the transistor's channel can be formed on three or more surfaces of the fin, so that the finFET can exhibit a high current switching capability for a given surface area occupied on substrate. Since the channel and device can be raised from the substrate surface, there can be reduced electric field coupling between adjacent devices as compared to conventional planer MOSFETs.

The second type of transistor is called a fully-depleted, silicon-on-insulator or “FD-SOI” FET. The channel, source, and drain of an FD-SOI FET are formed in a thin planar semiconductor layer that overlies a thin insulator. Because the semiconductor layer and the underlying insulator are thin, the body of the transistor (which lies below the thin insulator) can act as a second gate. The thin layer of semiconductor on insulator permits higher body biasing voltages that can boost performance. The thin insulator also reduces leakage current to the transistor's body region relative to the leakage current that would otherwise occur in bulk FET devices.

### SUMMARY

According to some embodiments, a method is provided, comprising: forming a fin on a substrate, forming a first layer covering the fin, forming a gate structure at least partially surrounding at least a portion of the fin and the first layer, and depositing a second layer on one or more side surfaces of the gate structure without depositing the second layer on the first layer at one or more side surfaces of the fin.

In some embodiments, forming the first layer comprises forming an oxide layer disposed at a top surface of the fin and at the one or more side surfaces of the fin.

In some embodiments, the gate structure comprises polysilicon.

In some embodiments, the second layer comprises a nitride layer.

In some embodiments, the nitride layer comprises a silicon nitride layer.

In some embodiments, depositing the second layer on one or more side surfaces of the gate structure without depositing the second layer on the on the first layer at the one or more side surfaces of the fin comprises using a selective nitridation process to deposit the nitride layer on the polysilicon layer at the one or more side surfaces of the gate structure without depositing the nitride layer on the oxide layer at the one or more side surfaces of the fin.

In some embodiments, the method further comprises forming a third layer on the first layer at the one or more side surfaces of the fin and on the second layer at the one or more side surfaces of the gate structure.

In some embodiments, the second and third layers comprise a nitride and collectively form a nitride layer, and a first thickness of the nitride layer disposed on a first of the one or more side surfaces of the gate structure is greater than a second thickness of the nitride layer disposed on a first of the one or more side surfaces of the fin.

In some embodiments, the nitride layer covers the one or more side surfaces of the gate structure, the top surface of the gate structure, and a portion of the gate structure forming a peripheral boundary between the one or more side surfaces of the gate structure and the top surface of the gate structure.

In some embodiments, the method further comprises etching the nitride layer to remove the nitride layer from the first layer covering the fin, and to form spacers at the one or more side surfaces of the gate structure.

In some embodiments, the method further comprises etching to remove the first layer from the side surfaces of the fin and a top surface of the fin; and doping first and second portions of the fin to form respective drain and source junctions of a finFET.

In some embodiments, the gate structure comprises a sacrificial gate, and the method further comprises removing the sacrificial gate; and forming a gate conductor of a finFET in an area from which the sacrificial gate was removed.

In some embodiments, the fin forms part of a finFET.

In some embodiments, the substrate comprises a silicon substrate, the fin comprises silicon, and the first layer comprises ethylene oxide.

In some embodiments, the silicon substrate comprises a bulk silicon substrate or a silicon-on-insulator substrate.

According to some embodiments, a method is provided, comprising: forming a fin on a substrate, forming a first layer covering the fin, forming a gate structure at least partially surrounding at least a portion of the fin, and selectively depositing a spacer layer over the substrate, wherein the spacer layer is deposited with a first thickness on one or more side surfaces of the gate structure and with a second thickness, less than the first thickness, on the first layer at one or more side surfaces of the fin.

In some embodiments, forming the first layer comprises forming an oxide layer disposed at a top surface of the fin and at the one or more side surfaces of the fin.

In some embodiments, the gate structure comprises polysilicon.

In some embodiments, the spacer layer comprises a nitride layer.

In some embodiments, the nitride layer comprises a silicon nitride layer.

In some embodiments, selectively depositing the spacer layer comprises depositing second and third layers over the substrate, and the second and third layers collectively form the spacer layer.

In some embodiments, depositing the second layer over the substrate comprises selectively depositing the second layer on the one or more side surfaces of the gate structure without depositing the second layer on the first layer at the one or more side surfaces of the fin.

In some embodiments, depositing the third layer comprises depositing the third layer on the first layer at the one or more side surfaces of the fin and on the second layer at the one or more side surfaces of the gate structure.

In some embodiments, the second layer comprises a first nitride layer, and the third layer comprises a second nitride layer.

In some embodiments, the first and second nitride layers comprise silicon nitride.

In some embodiments, depositing the second and third layers over the substrate comprises depositing the second and third layers in consecutive steps of a semiconductor fabrication process.

In some embodiments, depositing the spacer layer over the substrate comprises forming the spacer layer without etching the spacer layer.

In some embodiments, the fin forms part of a finFET.

According to some embodiments, a device is provided, comprising: a fin formed on a substrate, a first layer covering the fin, a gate structure at least partially surrounding at least a portion of the fin, and second and third layers formed over the substrate, wherein the second and third layers collectively form a spacer layer, wherein the spacer layer is disposed on one or more side surfaces of the gate structure and at one or more side surfaces of the fin, and wherein the spacer layer has a first thickness at the one or more side surfaces of the gate structure and a second thickness, less than the first thickness, at the one or more side surfaces of the fin.

According to some embodiments, a device is provided, comprising first and second parallel semiconductor fins formed on a substrate separated with a pitch between approximately 10 nm and 30 nm.

In some embodiments, the fin pitch is between approximately 10 nm and 20 nm.

In some embodiments, the fin pitch is between approximately 10 nm and 15 nm.

### BRIEF DESCRIPTION OF THE DRAWINGS

One of ordinary skill in the art will understand that the figures, described herein, are for illustration purposes only. It is to be understood that in some instances various aspects of the illustrated embodiments may be shown exaggerated or enlarged to facilitate an understanding of the embodiments. In the drawings, like reference characters generally refer to like features, functionally similar elements and/or structurally similar elements throughout the various figures. The drawings are not necessarily to scale, emphasis instead being placed upon illustrating the principles of the teachings. Where the drawings relate to fabrication of integrated devices, an illustrated device may be representative of a large plurality of devices that may be fabricated in parallel. The drawings are not intended to limit the scope of the present teachings in any way.

FIG. 1 shows an elevation view of an FD-SOI FET;

FIG. 2 shows a perspective view of a finFET;

FIG. 3A shows a cross-sectional view of a finFET;

FIG. 3B shows a cross-sectional view of a finFET;

FIG. 4 shows a flowchart of semiconductor processing method;

FIG. 5 shows a perspective view of a finFET;

FIGS. 6A, 6B, and 6C show cross-sectional views of finFET along A-A′, B-B′, and C-C′, respectively, after a portion of a fabrication process;

FIGS. 7A, 7B, and 7C show cross-sectional views of finFET along A-A′, B-B′, and C-C′, respectively, after another portion of a fabrication process;

FIGS. 8A, 8B, and 8C show cross-sectional views of finFET along A-A′, B-B′, and C-C′, respectively, after another portion of a fabrication process;

FIGS. 9A, 9B, and 9C show cross-sectional views of finFET along A-A′, B-B′, and C-C′, respectively, after another portion of a fabrication process; and

FIGS. 10A, 10B, and 10C show cross-sectional views of finFET along A-A′, B-B′, and C-C′, respectively, after another portion of a fabrication process.

### DETAILED DESCRIPTION

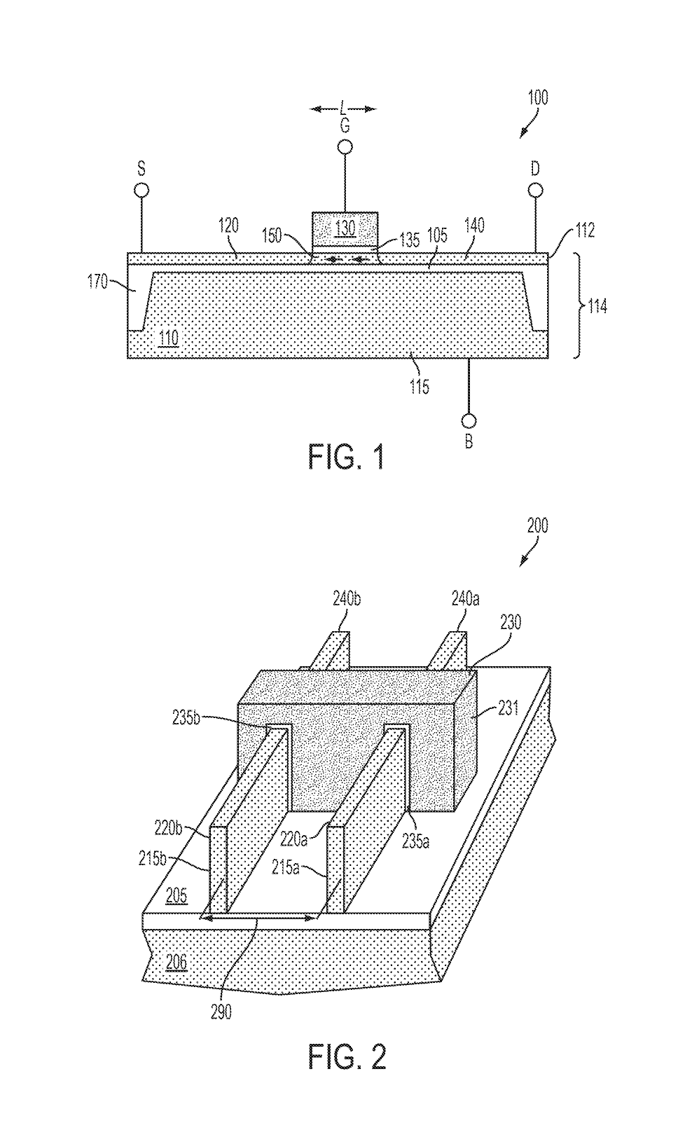

An example of a fully-depleted silicon-on-insulator (FD-SOI) FET 100 is depicted in FIG. 1. The FD-SOI FET comprises a source region 120, a gate structure 130, 135, a drain region 140, and a channel region 150. The source, channel, and drain regions are formed in a thin semiconductor layer 112 that is formed adjacent an insulating layer 105 (e.g., a thin insulating layer or buried oxide layer). The insulating layer 105 is formed adjacent a substrate layer 110. The substrate layer 110, insulating layer 105, and thin semiconductor layer 112 collectively form a silicon-on-insulator (SOI) substrate 114. In an example, the semiconductor layer 112 and insulating layer 105 are ultrathin, e.g., less than about 35 nm or less than about 20 nm. Such devices may be referred to as ultra-thin body and buried oxide (UTBB) devices. In a UTBB structure, the insulating layer 105 may be less than about 30 nm in thickness, with a preferred thickness of about 25 nm for some embodiments, and the semiconductor layer 112 may be less than about 10 nm, with a preferred thickness of about 7 nm for some embodiments. Trench isolation structures 170 comprising electrically-insulating material are formed around one or more FD-SOI FETs. The gate structure comprises a gate conductor 130 and a thin gate insulator 135. Integrated source S, gate G, drain D, and body B interconnects provide electrical connections to the source, gate, drain, and back body regions of the FD-SOI FET.

The source region 120 and drain region 140 of an FD-SOI FET are doped with acceptor or donor impurities to form regions of a first conductivity type (e.g., p-type or n-type). The channel region 150 may be doped to be of an opposite conductivity type, and may be of a same conductivity type as a back body region 115 (e.g., partially-depleted SOI or PD-SOI). Alternatively, the channel region 150 may be undoped (referred to as a fully-depleted (FD) SOI structure). An FD-SOI FET can exhibit reduced leakage currents compared to bulk FET devices and offer flexible bias strategies for improving speed or reducing threshold voltages for low-voltage applications.

An example of a finFET 200 is depicted in the perspective view of FIG. 2. The finFET is fabricated on a bulk semiconductor substrate 206, e.g., a bulk silicon substrate, and comprises one or more fin-like structures (215a, 215b) that run in a length direction along a surface of the substrate and extend in a height direction normal to the substrate surface. The fins 215 may have narrow widths, e.g., less than 50 nanometers. There may be an electrically-insulating layer 205, e.g., an oxide layer, on a surface of the substrate 206. The fins 215 may pass through the insulating layer 205, but be attached to the semiconducting substrate 206 at a lower region (e.g., “base”) of the fin. A gate structure 230 comprising a conductive gate material 231 (e.g., polysilicon) and a gate insulator (235a, 235b) (e.g., an oxide and/or a high dielectric constant material) is formed over a region of the fin. The finFET further includes a source region (220a, 220b) and drain region (240a, 240b) adjacent to the gate. Include integrated source S, gate G, drain D, and body B interconnects (not shown) provide electrical connections to the source, gate, drain, and back body regions of the device.

During operation of the finFET, the entire fin portion encased by the gate structure may be inverted and form a bulk channel rather than a surface channel. A metallic film may be deposited between a gate electrode 231 and gate oxide 235 (e.g., to improve gate conductance and/or gate switching speeds).

FinFETs like the finFET depicted in FIG. 2 exhibit favorable electrostatic properties for scaling to high-density, low-power, integrated circuits. Because the fin and channel are raised from the substrate, cross-coupling between proximal devices is reduced relative to cross-coupling between conventional FETs. For the device shown in FIG. 2, the fins 215 may be formed from the bulk substrate 206 by an etching process, and therefore may be attached to the substrate 206 at base regions of the fins, regions which are occluded in the drawing by the adjacent insulator 205. The insulator 205 is formed after the etching of the fins 215. Because the fins 215 are attached to the semiconductor substrate, leakage current and cross-coupling may occur via the base region of the fin.

Alternatively, the finFETs may be formed on an SOI substrate. When a finFET is formed on an SOI substrate, the fins are attached to the thin semiconductor layer of the SOI substrate at base regions of the fins, or the fins are formed by etching through the insulating layer of the SOI substrate such that the base regions of the fins are attached to the substrate layer of the SOI substrate.

Source, channel, and drain regions of a finFET are doped with donor or acceptor impurities to create different regions of different conductivity types. Several different configurations of source, channel, and drain regions are possible. In an embodiment, source region 220 and drain region 240 are doped to be of a first conductivity type and the channel region 250 are doped to be of an opposite conductivity type (or may be undoped). The terms “source region” and “drain region” as used may include extension regions of the fins that lie between source and drain contact regions and the channel region of the finFET device.

The finFET may further include a body region made of a same conductivity type as the channel region, or may be undoped (e.g., like the channel region). The doping of source and drain regions in a finFET may be of various geometries. In some embodiments, vertical portions of the fin 215 may be doped to form source 220 and drain 240 regions. Alternatively, according to some embodiments, outer sheath portions of a fin 215 may be doped to form source and drain regions.

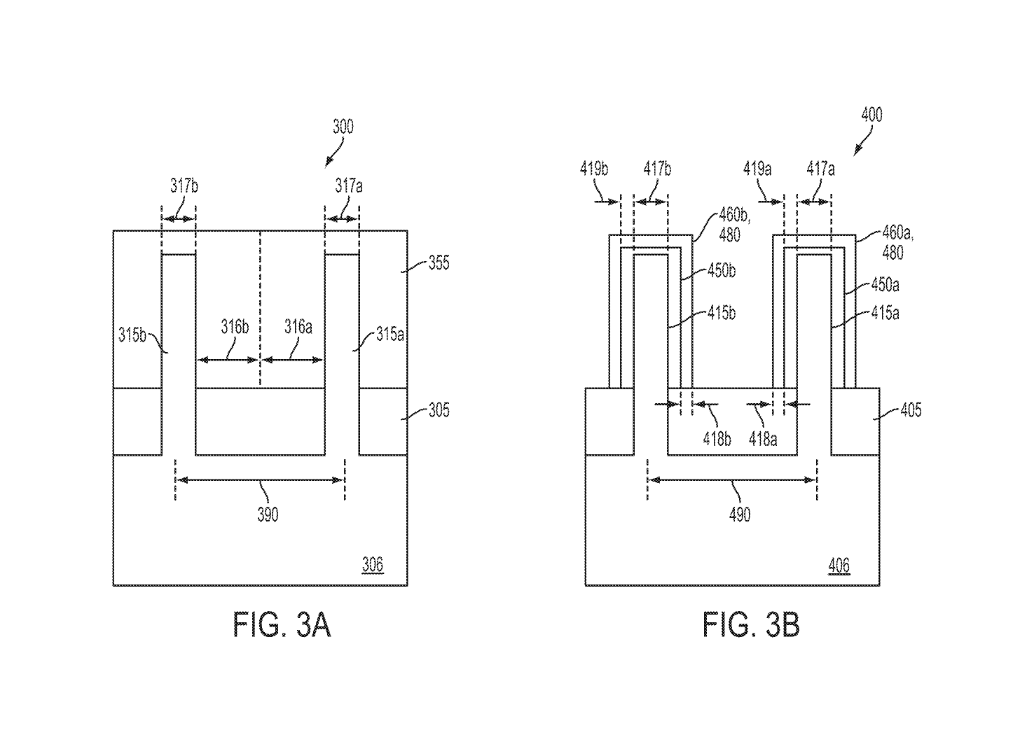

As has been consistent since the early days of semiconductor device manufacturing, minimum feature sizes of semiconductor devices continue to shrink with each next generation of devices, or manufacturing “node,” allowing a corresponding increase in the density of devices on an integrated circuit. This trend has been recognized and represented by the well-known Moore's law relationship. As finFETs reduce in size, the width of the fin becomes narrower, and the spacing between fins, or “fin pitch,” may also decrease. Some finFETs may comprise multiple fins per device, and a reduction in fin pitch may allow an increase in the number of fins for the device and the amount of current switched by the finFET. The inventors have recognized that some processing techniques used for manufacturing finFETs may not be suitable for making finFETs where the fin pitch becomes less than about 30 nm. Problems associated with these processing techniques are described in connection with FIG. 3 A.

FIG. 3A depicts a cross-sectional view of a finFET 300 after a spacer layer 355 is formed over a substrate 306 (e.g., a bulk silicon substrate). FinFET 300 includes two fins (315a, 315b), each of which is attached to substrate 306 at the fin's base. The fins may be formed using a sidewall image transfer process (SIT), a mandrel process, or any other suitable fin-formation process, according to some embodiments. An electrically-insulating layer 305 is formed on substrate 306. In some cases, an insulating layer (not shown) may be formed on the portion of the fin that extends above insulating layer 305, and subsequently removed from the portion of the fin not covered by the gate during an earlier stage of fabrication. A spacer layer 355 (e.g., a gate spacer layer) may be formed on a gate overlying the fins and also cover the fins (315a, 315b). The spacer layer 355 may be a nitride layer, according to one processing technique. Due to constraints imposed by the processing technique, the spacer layer may be required to have a minimum thickness for adequately covering the gate.

According to one processing technique, the fins may be formed with a fin width (317a, 317b) of approximately 8 nm, and the spacer layer 355 may be subsequently deposited at a minimum thickness (316a, 316b) of approximately 8 nm. As can be seen, for a fin pitch 390 of approximately 24 nm, the portions of spacer layer 355 formed on fin 317a and fin 317b merge together, “pinching off” the space between the fins. When deposition of the spacer layer leads to pinch-off between the fins, it may be difficult to reliably remove the spacer layer from the fins without damaging the fins. The same difficulties would be encountered in other configurations where the spacing between adjacent fins is approximately equal to or less than twice the minimum spacer layer thickness (e.g., if the minimum spacer layer thickness were about 10 nm and the fin width were about 10 nm in the example of FIG. 3A). Accordingly, the processing technique illustrated in FIG. 3A may be unsuitable for reliably fabricating finFETs with fin pitch of approximately 30 nm or less.

A technique for reliably fabricating finFETs with fin pitch of less than approximately 30 nm is illustrated in FIG. 3B, which shows a cross-sectional view of a finFET 400 after a spacer layer 480 is formed over a substrate 406. The technique illustrated in FIG. 3B may be used to fabricate finFETs with fin pitch between approximately 15 nm and approximately 30 nm, including, but not limited to, fin pitch between approximately 15 nm and approximately 24 nm. The technique for reliably fabricating finFETs with fin pitch of less than approximately 30 nm includes a technique for forming a spacer layer wherein a thickness of a portion of the spacer layer deposited adjacent a gate structure of the finFET is greater than a thickness of a portion of the spacer layer deposited adjacent a fin of the finFET. The difference in layer thicknesses at the gate and fins occurs during a same deposition step. The technique for reliably fabricating finFETs with fin pitch of less than approximately 30 nm may be used in any semiconductor processing in any suitable semiconductor processing node, including, but not limited to, the 10 nm node, the 7 nm node, the 5 nm node, and/or nodes with minimum features less than 5 nm.

In the example of FIG. 3B, substrate 406 is illustrated as a bulk substrate (e.g., a bulk silicon substrate) with an insulating layer 405 formed adjacent the substrate. Insulating layer 405 may include, but is not limited to, one or more layers of silicon oxide and/or any other suitable electrically-insulating material. Although substrate 406 is illustrated as a bulk substrate in the example of FIG. 3B, the techniques described herein are not limited to devices formed on bulk substrates, and may be applied to devices formed on silicon-on-insulator (SOI) substrates including ultra-thin body and buried oxide (UTBB) substrates, and/or any other suitable substrates. In embodiments where the substrate is an SOI or UTBB substrate, insulating layer 405 may comprise the buried oxide (BOX) layer of the SOI substrate.

In the example of FIG. 3B, a protective layer 450 is formed adjacent the portions of the fins (415a, 415b) that extend above insulating layer 405 and covers the fins. Protective layer 450 may include one or more layers of insulating materials, including, but not limited to, silicon oxide, ethylene-type oxide (e.g., ethylene oxide, ethylene glycol oxide), any other suitable oxide, and/or any other suitable insulating material. The thickness of protective layer 450 may be between about 2 nm and about 4 nm.

In the example of FIG. 3B, a spacer layer 480 is formed adjacent the fins (415a, 415b), covering the fins and protective layer 450. The spacer layer 480 may include, but is not limited to, a nitride (e.g., silicon nitride, SiOCN, SiPCN, and/or any other suitable nitride), a boron silicide (SiB), any material suitable for forming a gate spacer structure, and/or any other suitable material. The portions of layer 480 formed adjacent the fins may have a thickness 418 of approximately 2-4 nm. The portions of layer 480 formed adjacent a gate structure of finFET 400 may function as gate spacers during a gate replacement process. The portions of layer 480 formed adjacent the finFET's gate structure are thicker than portions of layer 480 formed adjacent the finFET's fins. For example, portions of layer 480 formed adjacent the finFET's gate structure may have a thickness of approximately 5-10 nm. A layer thickness of 5-10 nm adjacent to the finFET's gate structure may facilitate proper formation of the finFET gate, while a layer thickness of 2-4 nm adjacent to the finFET's fins may facilitate reduction of the finFET's fin pitch.

The portions of layer 480 adjacent the finFET's gate structure form gate spacers, and may require a minimum thickness of (e.g., 5-10 nm) to function properly as gate spacers. However, forming the portions of layer 480 adjacent the finFET's fins with the same thickness as the gate spacers may pinch off the space between the fins, particularly in devices where the fin pitch is small. Thus, forming layer 480 with differential thickness in the regions adjacent the finFET's gate structure and the regions adjacent the finFET's fins facilitates formation of a suitable gate spacer without pinching off the space between the finFET's fins.

The deposition of a spacer layer 480 having greater thickness adjacent the finFET gate structure and less thickness adjacent the finFET fin is achieved using the process technique described herein. In some embodiments, the layer 480 of material may include two or more sub-layers. In some embodiments, portions of layer 480 formed adjacent the finFET's gate structure may include a first sub-layer 460 and a second sub-layer (not illustrated in FIG. 3B), while portions of layer 480 formed adjacent the finFET's fins may include only the first sub-layer 460. Each of the two or more sub-layers included in layer 480 may include, but is not limited to, a nitride (e.g., silicon nitride, SiOCN, SiPCN, and/or any other suitable nitride), a boron silicide (SiB), any material suitable for forming a gate spacer structure, and/or any other suitable material.

Using embodiments of the technique illustrated in FIG. 3B, a finFET with a fin pitch between approximately 10 nm and approximately 30 nm may be fabricated, and in some embodiments a fin pitch of approximately 15-24 nm) may be reliably fabricated. In the example of FIG. 3B, the fin widths (417a, 417b) may be between approximately 3 nm and approximately 10 nm in some embodiments, approximately 3-5 nm in some embodiments, approximately 5-7 nm in some embodiments, approximately 8-10 nm in some embodiments, or approximately 8 nm in some embodiments. The thickness (419a, 419b) of protective layer 450 may be approximately 2-4 nm, and the thickness (418a, 418b) of the portions of spacer layer 480 adjacent the fins may be approximately 3-6 nm in some embodiments. For example, in some embodiments, a fin pitch as low as approximately 14 nm (14 nm>fin width+2*insulating layer thickness+2*thickness of layer 480 adjacent fins=3 nm+2*2 nm+2*3 nm)=13 nm) may be obtained using the configuration illustrated in FIG. 3B. In some embodiments, the fin pitch may be further reduced as low as approximately 10 nm by removing protective layer 450 from the portions of the fins (415a, 415b) not covered by the finFET gate prior to forming layer 480 (10 nm>fin width+2*thickness of layer 480 adjacent fins=3 nm+2*3 nm=9 nm).

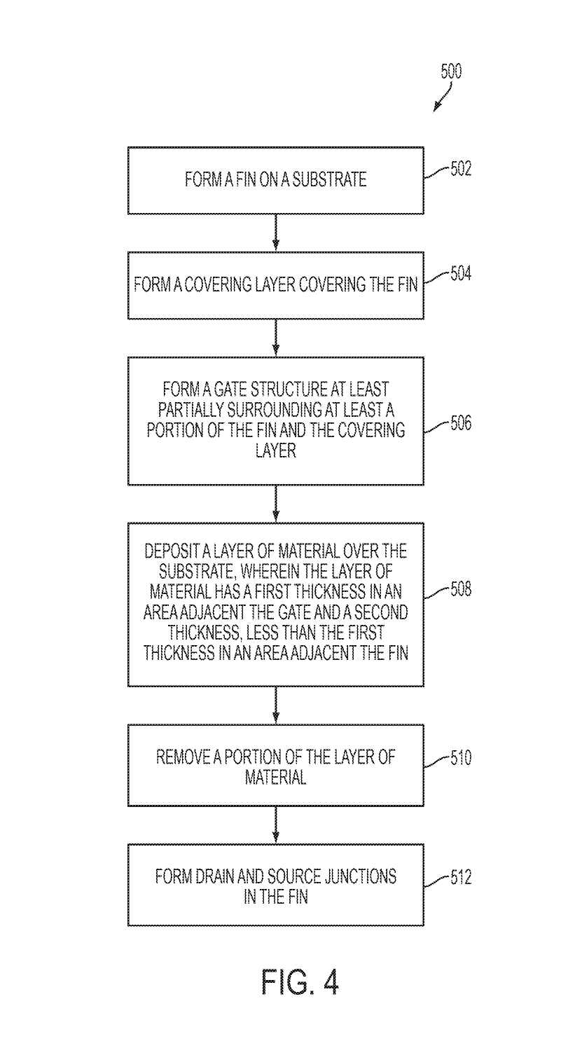

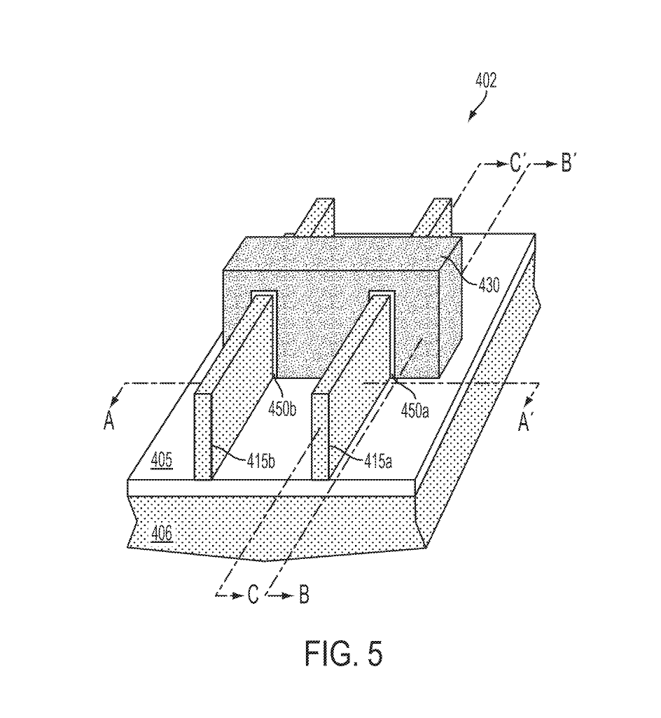

FIG. 4 shows a flowchart that provides an overview of a semiconductor processing method 500. In some implementations, there may be more or fewer acts than those depicted in FIG. 4. The method 500 may be used to fabricate a finFET, such as the finFET 402 illustrated in FIG. 5. In the example of FIG. 5, finFET 402 is formed over a substrate 406 and an insulating layer 405. FinFET 402 includes one or more fins 415, a gate structure 430, and a protective layer 450 formed between the one or more fins 415 and the gate structure 430. For brevity, descriptions of embodiments of substrate 406, insulating layer 405, fin(s) 415, and protective layer 450, which are given above with reference to FIG. 3B, are not repeated here.

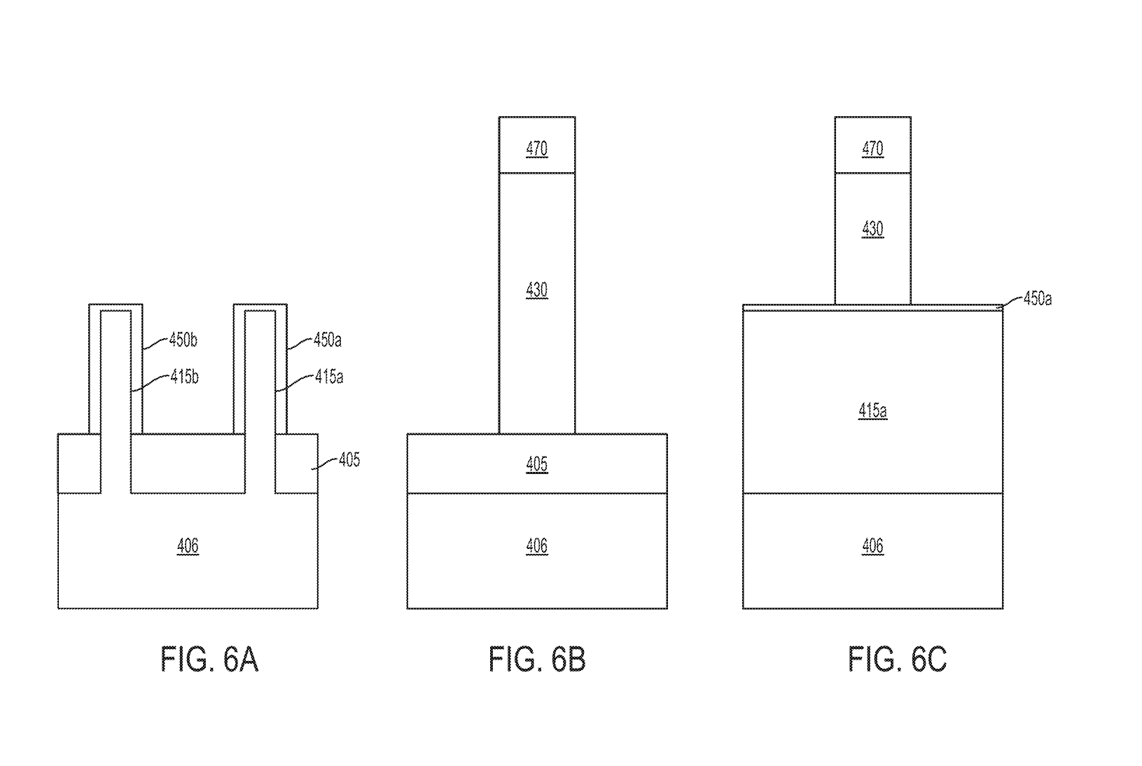

Some of the acts 502-512 of method 500 are illustrated in FIGS. 6A-10C, which depict various stages in the formation of finFET 402. Each of FIGS. 6A-10A depicts a cross-section of finFET 402 along A-A′. Each of FIGS. 6B-10B shows a cross-section of finFET 402 along B-B′. Each of FIGS. 6C-10C depicts a cross-section of finFET 402 along C-C′.

FIGS. 6A-6C illustrate cross-sections of finFET 402 after completion of acts 502-506 of method 500s. At act 502, one or more fins are formed on a substrate. The fin(s) may be formed on the substrate by any suitable process (e.g., using sidewall image transfer (SIT) techniques, a mandrel process, lithographically patterning a resist and etching portions of the substrate to form the fin(s), or by patterning and etching trenches and depositing semiconductor material in the trenches to form the fins). In some implementations, lithographic patterning may be done using extreme ultraviolet (EUV) lithography.

In some embodiments, an insulating layer 405 may be formed over the substrate adjacent to lower portions of the fin(s). The insulating layer 405 may be formed by depositing insulating material over the substrate, by etching portions of an insulating material, and/or by any other suitable technique. FIG. 6A illustrates two fins (415a, 415b) formed on a substrate 406, with an insulating layer 405 formed over substrate 406 adjacent to lower portions of the fins. The fins (415a, 415b) may have widths between approximately 3 nm and approximately 10 nm, and in some embodiments widths of approximately 8 nm.

At act 504, a protective layer 450 is formed over the substrate, at least partially covering the finFET's one or more fins. The protective layer 450 may be formed over the substrate by any suitable process that deposits or otherwise forms a layer of suitable material at least over one or more fins. In some embodiments, the protective layer 450 may be formed locally on the substrate to cover one or more fins within a selected region of the substrate. In the example of FIG. 6A, protective layer 450 covers fins 415a and 415b. The protective layer 450 may be disposed adjacent to and/or on a top surface of a fin. The protective layer may be disposed adjacent to and/or on side surfaces of a fin. The protective layer 450 may conformally coat the fin and form a substantially uniformly-thick layer on exposed surfaces of the fin. In the example of FIG. 6A, the protective layer 450 is disposed adjacent to and on the top and side surfaces of fins 415a and 415b. The protective layer 450 may have a thickness between approximately 2 nm and approximately 4 nm. The protective layer 450 may include one or more layers and/or materials, including, but not limited to, silicon oxide, ethylene-type oxide, any other suitable oxide, and/or any other suitable insulating material. The protective layer may include a material on which a nitride does not form (or on which a nitride forms slowly relative to the rate of nitride formation on gate structure 430) during at least one processing step in which a nitride forms on gate structure 430 (e.g., a step of forming a spacer layer (or portion thereof) on the gate structure).

At act 506, a gate structure is formed over the substrate, at least partially surrounding at least a portion of the finFET's one or more fins and the protective layer. The gate structure is formed by depositing one or more layers over the substrate followed by the use of lithographic techniques to pattern a gate structure over the fins. For example, a poly-silicon layer is deposited over the fins, and may be planarized. A hard mask (e.g., a silicon nitride mask) is deposited and patterned over the poly-silicon layer. The hard mask is then patterned using photolithography techniques and etching. The patterning of the hard mask is transferred to the poly-silicon via etching to form the gate structure. Other suitable techniques and materials may be used in other embodiments to form the gate structure.

In some embodiments, gate structure 430 may include, but is not limited to, a sacrificial gate, a gate conductor of finFET 402, one or more spacers, a gate insulator, any other suitable layer, and/or any other suitable material. A sacrificial gate may include one or more layers and/or materials formed as a “dummy gate” for the finFET 402, and subsequently removed prior to formation of the finFET's gate conductor. The sacrificial gate may include, but not limited to, one or more layers of polysilicon. A gate conductor may include one or more layers and/or materials configured such that a voltage applied thereto controls a current between the finFET's source and drain (e.g., one or more layers of polysilicon and/or metallic material). A spacer may include one or more layers and/or materials (e.g., one or more nitride layers) disposed at sidewalls of the gate structure adjacent source and drain regions of the finFET. A gate insulator may include one or more layers and/or materials disposed adjacent to the finFET channel and configured to insulate the gate conductor from the channel (e.g., one or more layers of silicon oxide, ethylene-type oxide, and/or any other suitable material).

In the example of FIGS. 6B and 6C, gate structure 430 partially surrounds fins 415a and 415b and protective layer 450, and a portion of a hard mask 470 is disposed at the top surface of gate structure 430. The gate structure may be formed at act 506 as a sacrificial gate, comprising material to be removed prior to deposition of the gate conductor in a subsequent process step. In some embodiments, the sacrificial gate of FIG. 6 may include one or more layers of polysilicon and/or any suitable material.

At act 508, a spacer layer 480 is deposited over the substrate. The spacer layer is disposed on one or more side surfaces of the gate structure, on a top surface of the gate structure (e.g., on a top surface of hard mask layer disposed at a top surface of the gate structure), on one or more side surfaces of a fin (e.g., on the “protective layer” disposed at one or more side surfaces of the fin), and/or on the top surface of the fin (e.g., on the “protective layer” disposed at the top surface of the fin). The thickness of the spacer layer in a region adjacent (e.g., on) a side surface of the gate structure exceeds a thickness of the spacer layer in regions adjacent (e.g., on) top and/or side surfaces of the fin(s).

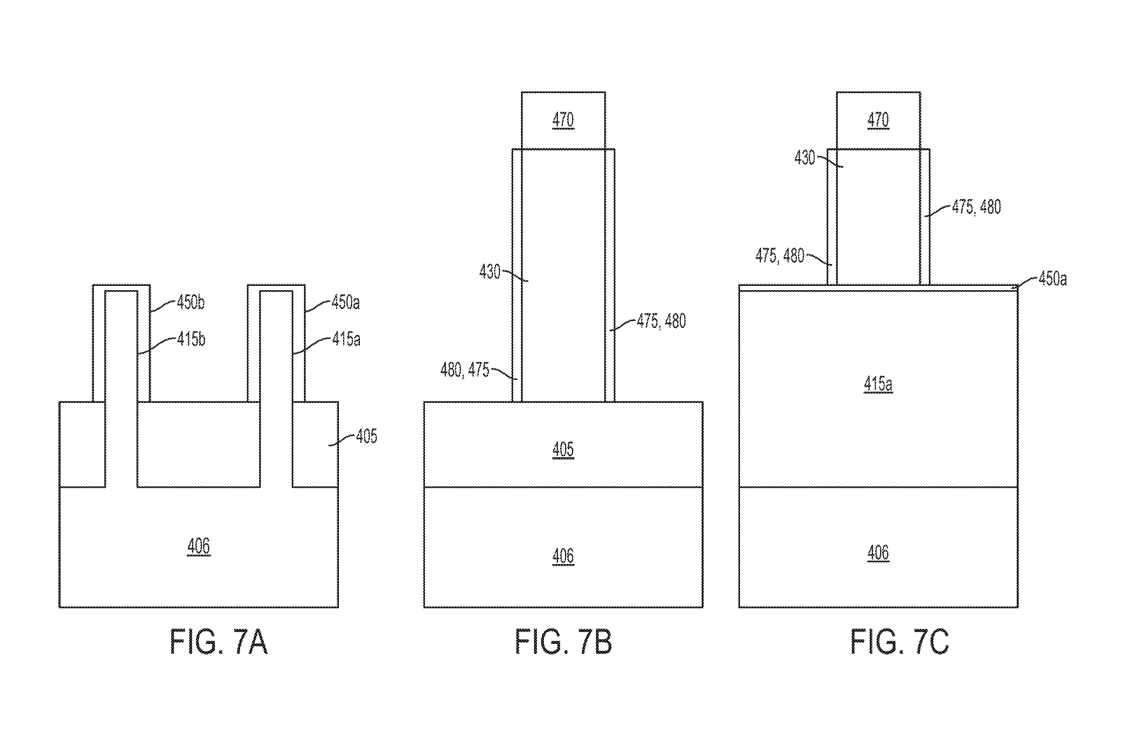

The deposition of the spacer layer 480 in act 508 may include a process step of forming (e.g., depositing) a first sub-layer 475. The first sub-layer 475 is formed on one or more side surfaces of the gate structure without forming the first sub-layer adjacent to one or more top and/or side surfaces of the fin(s) (e.g., without forming the first sub-layer on the protective layer 450 disposed adjacent to the top and/or side surfaces of the fin(s), or with minimal formation of the first layer on the fin surfaces), as depicted in FIGS. 7A-7C. In some embodiments, the first sub-layer 475 may be formed on one or more side surfaces of the gate structure at a rate that exceeds the first sub-layer's rate of formation adjacent to one or more top and/or side surfaces of the fin(s) by a factor of at least two, a factor between two and five, a factor between five and ten, a factor between ten and twenty, a factor between twenty and fifty, or a factor greater than fifty.

For example, the first sub-layer 475 may be formed (e.g., deposited) using a selective formation (e.g., selective deposition) process (e.g., selective nitridation process) in which a material (e.g., a nitride) is formed on some materials (e.g., silicon and/or polysilicon such as at the gate) but not others (e.g., oxide, such as silicon oxide and/or ethylene-type oxide such as at the fins), or formed on some materials (e.g., silicon and/or polysilicon such as at the gate) at faster rates than on other materials (e.g., oxide, such as silicon oxide and/or ethylene-type oxide such as at the fins). The selective formation process may include, but is not limited to, the selective nitridation process described in U.S. patent application Ser. No. 13/623,620, filed Sep. 20, 2012 and titled “Surface Stabilization Process to Reduce Dopant Diffusion,” now published as U.S. Pub. No. 2013/0109162, which is hereby incorporated by reference herein in its entirety; Applied Materials' commercially available Byron process; and/or any other suitable selective formation process.

FIGS. 7A-7C illustrate cross-sections of finFET 402 after formation of the first sub-layer 475 in act 508 of method 500. As can be seen in FIGS. 7B-7C, the first sub-layer 475 is formed adjacent to the side surfaces of gate structure 430. As can be seen in FIG. 7A, the first sub-layer 475 is not formed adjacent to the top or side surfaces of the fins 415. Though, in some embodiments, a very thin first sub-layer 475 may be formed adjacent to the top or side surfaces of the fins (e.g., the ratio of the thickness of the first layer on the side surfaces of the gate structure to the thickness of the first layer in regions adjacent to the top or side surfaces of the fins may be between approximately 2:1 and approximately 50:1, or greater).

The deposition of the spacer layer 480 further includes a process step of forming (e.g., depositing) a second sub-layer 460. In some embodiments, the first and second sub-layers may collectively form the spacer layer. In some embodiments, the first and second sub-layers may be deposited in distinct process steps (e.g., in successive (“consecutive”) process steps).

The second sub-layer 460 may be formed over the entire substrate, and thus the second sub-layer 460 is formed over the gate structure. The portion of the second sub-layer 460 formed over the gate structure covers the gate structure and the first sub-layer 475 formed in act 508. The second sub-layer 460 is further formed over the fin(s). The portion of the second layer formed over the fin(s) cover the fin(s) and the protective layer 450 formed in act 504 of method 500.

The second sub-layer 460 may be formed by any suitable process that deposits or otherwise forms the second sub-layer 460 to the wafer or die, including, but not limited to, epitaxy, physical vapor deposition (PVD), chemical vapor deposition (CVD), electrochemical deposition (ECD), molecular beam epitaxy (MBE), atomic layer deposition (ALD), and/or any suitable thin nitride deposition technique. In some embodiments, deposition of the second sub-layer 460 may comprise additive processes (processes which add material to the wafer or die, e.g., deposition) and/or modification processes (processes which modify properties of material on the wafer or die, e.g., doping) but not removal processes (processes which remove material from the wafer or die, e.g., etching). The second sub-layer 460 may be conformally deposited over the gate and fin structures. In some embodiments, the technique used to deposit the second sub-layer 460 may be atomic-layer deposition (ALD).

In some embodiments, the second sub-layer 460 may include the same material as the first sub-layer 475, or any suitable material.

In some embodiments, the protective layer 450 formed on the fins during act 504 of method 500 may be removed from portions of the fins not covered by gate structure 430 prior to formation of the second sub-layer 460 in act 508. Such removal of protective layer 450 may be carried out using etching and/or any technique suitable for removing exposed portions of the protective layer 450 from the semiconductor device. As discussed above, removing the protective layer 450 from the fins prior to formation the second sub-layer 460 in act 508 may facilitate fabrication of finFETs with reduced fin pitch.

The first and second sub-layers deposited in act 508 collectively form the spacer layer 480 deposited in act 508. In some embodiments, the spacer layer 480 may provide protective covering at the “corners” of gate structure 430 (e.g., the peripheral boundary between the top surface of gate structure 430 and the side surfaces of gate structure 430). The portion of the spacer layer 480 material covering the corners of gate structure 430 may prevent exposure of the gate conductor during a spacer etch and a parasitic epitaxial growth at the corners of the gate structure during a subsequent epitaxial step (e.g., a subsequent epitaxial step for forming a strained source and/or drain junction).

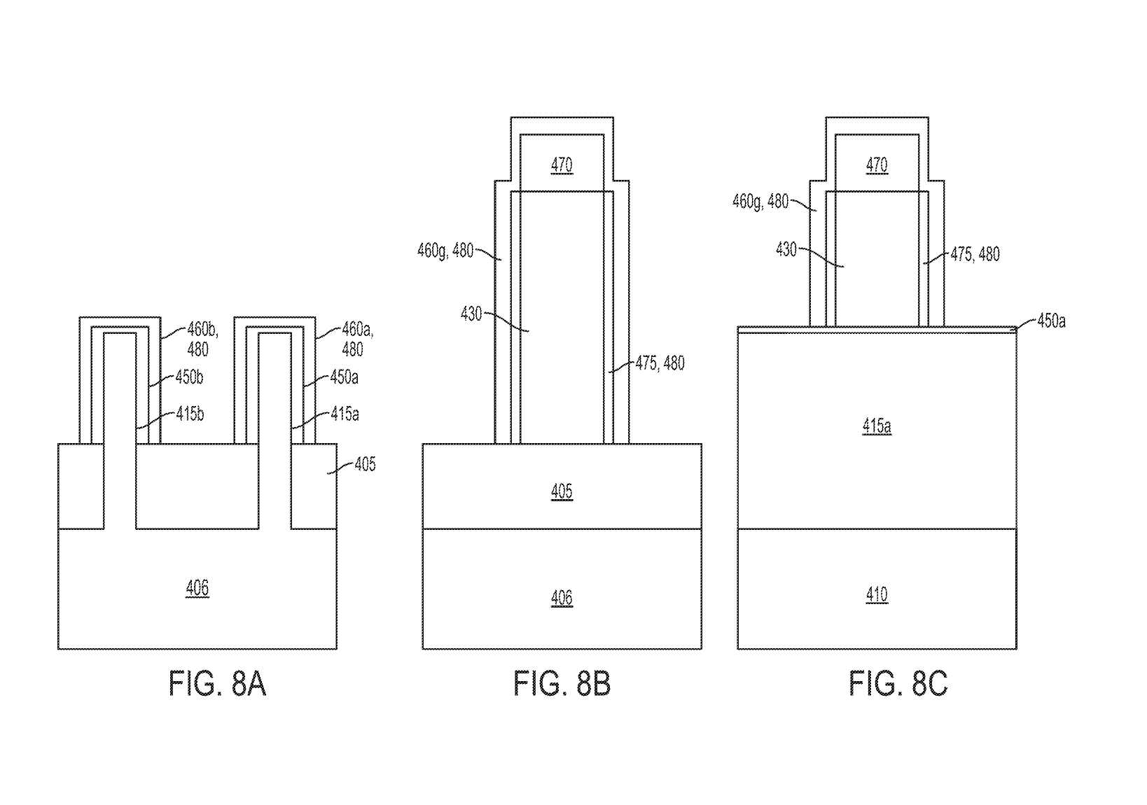

FIGS. 8A-8C illustrate cross-sections of finFET 402 after formation of the second sub-layer 460 in act 508 of method 500. As can be seen in FIGS. 8A-8C, the second sub-layer 460 is formed over gate structure 430 and over the fins (415a, 415b), covering gate structure 430, first layer 475, the fins 415, and protective layer 450 (if protective layer 450 has not been previously removed). Collectively, first sub-layer 475 and second sub-layer 460 form the spacer layer 480. In some embodiments, the thickness of the second sub-layer 460 of material may be between approximately 3 nm and approximately 6 nm. In some embodiments, the thickness of the spacer layer 480 in regions adjacent the side surfaces of gate structure 430 may be between approximately 5 nm and approximately 10 nm (the sum of the thicknesses of the first sub-layer and the second sub-layer).

Although a two-step process of forming the spacer layer 480 has been described, the spacer layer may be formed by any suitable process that deposits or otherwise selectively forms one or more suitable materials on the wafer or die, including, but not limited to, epitaxy, physical vapor deposition (PVD), chemical vapor deposition (CVD), electrochemical deposition (ECD), molecular beam epitaxy (MBE), sputtering, e-beam evaporation, and/or atomic layer deposition (ALD). In some embodiments, formation of the spacer layer 480 may comprise additive processes (processes which add material to the wafer or die, e.g., deposition) and/or modification processes (processes which modify properties of material on the wafer or die, e.g., doping) but not removal processes (processes which remove material from the wafer or die, e.g., etching). According to some embodiments, the spacer layer 480 forms selectively on exposed surfaces of the gate structure 430, but does not form, or minimally forms, at the fins (415a, 415b).

In act 510, a portion of the spacer layer 480 may be removed from finFET 402. The portion of the spacer layer 480 may be removed by etching (e.g., anisotropic etching and/or timed etching) or any other suitable technique. In some implementations, a short isotropic etch may be used to remove residual portions of the second sub-layer 460 of spacer layer 480 at the fins. In some embodiments, the removal process may remove all or substantially all of second sub-layer 460 of the spacer layer 480 from the regions adjacent the finFET's fins. In some embodiments, the removal process may remove only a portion of the second sub-layer 460 of the spacer layer 480 from the regions adjacent the gate structure's side surfaces, thereby forming gate spacers adjacent the gate structure's side surfaces.

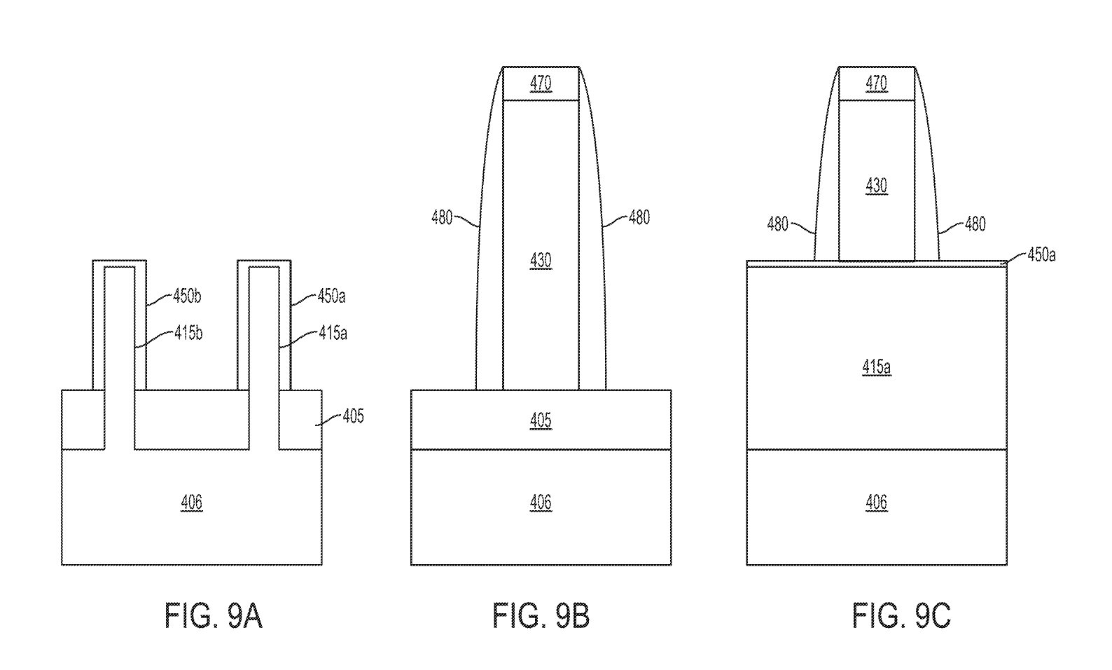

FIGS. 9A-9C illustrate cross-sections of finFET 402 after removal of a portion of the second sub-layer 460 of the spacer layer 480 in act 510 of method 500. As can be seen in FIG. 9A, the second sub-layer 460 of the spacer layer 480 has been removed from the regions adjacent the top and side surfaces of the fins (415a, 415b). As can be seen in FIGS. 9B-9C, portions of the second sub-layer 460 of the spacer layer 480 have been removed from regions adjacent the top and side surfaces of gate structure 430, and remaining portions of the second sub-layer 460 of spacer layer 480 form spacers adjacent the side surfaces of gate structure 430.

In act 512, drain and/or source junctions are formed in the finFET's fin(s). In some embodiments, forming the drain and/or source junctions may include a process step of removing portions of the protective layer 450 not covered by the gate structure from the top and/or side surfaces of the fin(s). A description of techniques for removing the protective layer 450 from the fins has been given above and is not repeated here. In some embodiments, after removing the protective layer 450, the drain and/or source junctions of the finFET are formed by doping the fins.

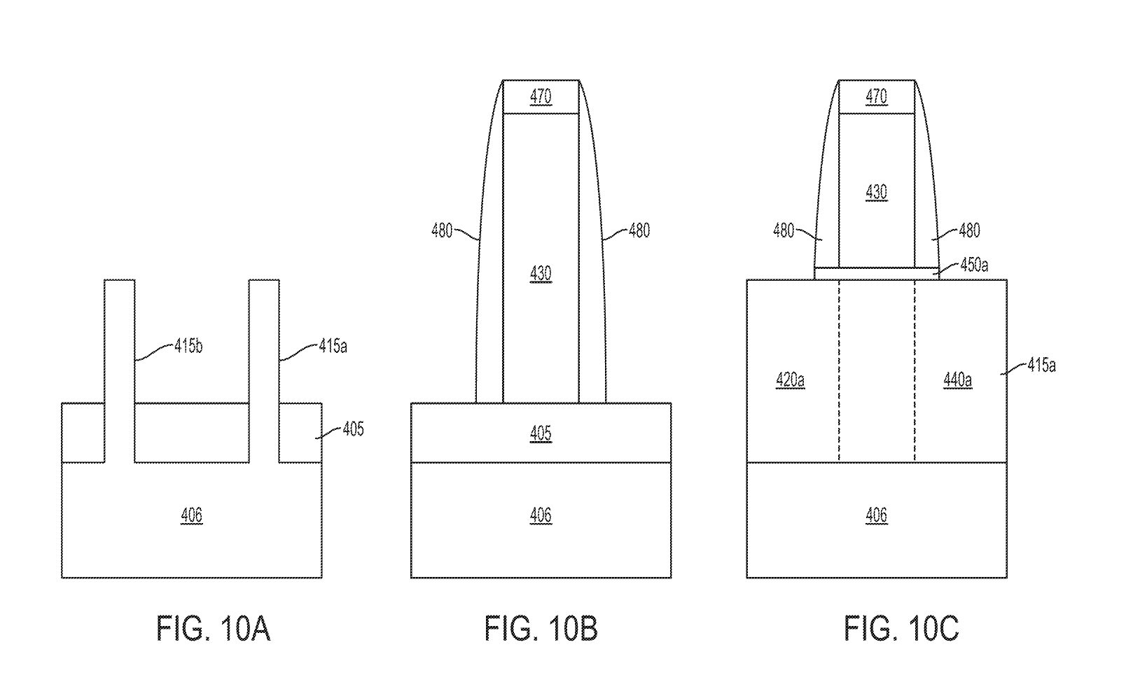

FIGS. 10A-10C illustrate cross-sections of finFET 402 after formation of the drain and source junctions in act 512 of method 500. As can be seen in FIGS. 10A and 10C, the protective layer 450 has been removed from portions of the fins not covered by gate structure 430. As can further be seen in FIG. 10C, source region 420a and drain region 440a have been formed in fin 415a by doping the fin.

In some embodiments, the techniques described herein may improve control over the locations of the source and drain junctions. In some embodiments, the source and drain junctions may be formed using ion implantation, where the remaining spacer after etching acts as a self-aligned, ion-implantation mask. By carefully controlling the thickness of the selective nitridation first sub-layer 475 and subsequent second sub-layer 460 (e.g., via ALD), the thickness of the spacer layer on the sidewalls of the gate can be determined to a high degree of precision. For example, the thickness of the spacer layer on the sidewalls of the gate can be determined to within about ±5 nm in some embodiments, and within about ±2 nm in some embodiments, and yet within about ±1 nm in some embodiments. By determining the thickness of the spacer layer with a high degree of precision, the locations of the source and drain junctions can be determined also with high precision.

In some embodiments, the techniques described herein may reduce damage to the fins during the finFET's fabrication, relative to conventional techniques.

The technology described herein may be embodied as a method, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments. Additionally, a method may include more acts than those illustrated, in some embodiments, and fewer acts than those illustrated in other embodiments. In some embodiments, a method may include a single act illustrated in FIG. 4, such as act 508. In some embodiments, a method may include act 508 and one or more additional acts illustrated in FIG. 4, such as acts 502-506. Additional acts of a method not illustrated in FIG. 4 may include, but are not limited to, straining a channel region of the device (e.g., by straining the source and drain junctions), replacing a sacrificial gate with a gate conductor, and/or any other suitable step.

Although embodiments of the techniques described herein have been described as conferring particular benefits, some embodiments of the techniques described herein may confer only one, fewer than all, or none of the described benefits.

Although embodiments of the techniques described herein have been described in relation to finFETs with fin pitch less than approximately 30 nm, the techniques described herein are not limited in this regard. In some embodiments, these techniques may be applied to finFETs with fin pitch greater than approximately 30 nm.

As used herein, an act of “forming” a layer may include any suitable process that deposits, grows, coats, transfers, or otherwise forms a layer of material on a wafer or die, including, but not limited to, epitaxy, physical vapor deposition (PVD), chemical vapor deposition (CVD), electrochemical deposition (ECD), molecular beam epitaxy (MBE), sputtering, e-beam evaporation, and/or atomic layer deposition (ALD). In some embodiments, forming a layer may comprise additive processes (processes which add material to the wafer or die), modification processes (processes which modify properties of material on the wafer or die), and/or removal processes (processes which remove material from the wafer or die, e.g., etching).

In some embodiments, the techniques described herein may be used to form semiconductor devices as components in integrated circuits.

Although the drawings depict one or a few transistor structures, it will be appreciated that a large number of transistors can be fabricated in parallel following the described semiconductor manufacturing processes. The transistors may be incorporated as part of microprocessing or memory circuitry for digital or analog signal processing devices. The transistors may be incorporated in logic circuitry, in some implementations. The transistors may be used in consumer electronic devices such as smart phones, computers, televisions, sensors, microprocessors, microcontrollers, field-programmable gate arrays, digital signal processors, application specific integrated circuits, logic chips, analog chips, and digital signal processing chips.

Although some of the foregoing methods and structures are described in connection with “finFETs,” the methods and structures may be employed for variations of finFET devices in some embodiments. For example, according to some implementations, the methods and structures may be employed for the fabrication of tri-gate, pi-gate, or omega-gate transistors. In some embodiments, the methods and structures may be employed for the fabrication of gate-all-around (GAA) transistors.

The terms “approximately,” “substantially,” and “about” may be used to mean within ±20% of a target dimension in some embodiments, within ±10% of a target dimension in some embodiments, within ±5% of a target dimension in some embodiments, and yet within ±2% of a target dimension in some embodiments. The terms “approximately,” “substantially,” and “about” may include the target dimension.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

1. A semiconductor processing method, comprising:
forming a protective layer on a semiconductor fin supported by a substrate;
forming a gate structure at least partially surrounding a channel portion of the semiconductor fin, said gate structure separated from the channel portion by the protective layer; and
forming a spacer layer on the gate structure and semiconductor fin, said spacer layer having a first thickness on the gate structure and a second thickness on the semiconductor fin, said second thickness being less than the first thickness, wherein forming the spacer layer comprises:
depositing a first sub-layer with a third thickness on sidewalls of the gate structure and a fourth thickness on the semiconductor fin, said fourth thickness being less than the third thickness; and
depositing a second sub-layer over the first sub-layer on the gate structure and on the semiconductor fin.

2. The method of claim 1, wherein forming the protective layer on the semiconductor fin comprises forming the protective layer on the channel portion of the semiconductor fin and on source and drain portions of the semiconductor fin on opposite sides of the channel portion, and wherein depositing the first sub-layer comprises depositing a material for the first sub-layer which preferentially deposits to a greater thickness on the sidewalls of the gate structure than on a material of the protective layer.

3. The method of claim 1, wherein the first sub-layer comprises a nitride layer.

4. The method of claim 3, wherein the nitride layer comprises a silicon nitride layer.

5. The method of claim 3, wherein depositing the first sub-layer comprises using a selective nitridation process to deposit the nitride layer on the sidewalls of the gate structure without depositing the nitride layer on the protection layer present on the semiconductor fin.

6. The method of claim 3, wherein depositing the first sub-layer comprises using a selective nitridation process to deposit the nitride layer on the sidewalls of the gate structure with the third thickness and deposit the nitride layer on the protection layer present on the semiconductor fin with the fourth thickness.

7. The method of claim 1, further comprising selectively removing all or substantially all of the second sub-layer from the semiconductor fins while leaving at least some of the second sub-layer with the first sub-layer on the semiconductor gate to form sidewall spacers structures for a transistor gate.

8. The method of claim 7, further comprising:
etching to remove the protective layer from surfaces of the semiconductor fin; and
doping first and second portions of the semiconductor fin on opposite sides of the channel portion to form respective drain and source junctions.

9. The method of claim 8, wherein the gate structure comprises a sacrificial gate, and wherein the method further comprises:
removing the sacrificial gate; and
forming a gate conductor of a finFET in an area from which the sacrificial gate was removed.

10. The method of claim 1, wherein the fin forms part of a finFET.

11. The method of claim 1, wherein the substrate comprises a silicon substrate, wherein the fin comprises silicon, and wherein the protective layer comprises ethylene oxide.

12. The method of claim 11, wherein the silicon substrate comprises one of a bulk silicon substrate or a silicon-on-insulator substrate.

13. A semiconductor device, comprising:
a semiconductor fin on a substrate;
a protective layer covering the semiconductor fin;
a gate structure at least partially surrounding a channel portion of the semiconductor fin; and
a first sub-layer formed over the substrate with a first thickness on the gate structure and a second thickness on the semiconductor fin, the second thickness being less than the first thickness; and
a second sub-layer formed over the substrate on the gate structure and on the semiconductor fin;
the first and second sub-layers forming a spacer layer having a third thickness on the gate structure and a fourth thickness on the semiconductor fin, said fourth thickness being less than the third thickness.

14. The semiconductor device of claim 13, where said semiconductor fin comprises first and second parallel semiconductor fins formed on said substrate and separated with a fin pitch between approximately 10 nm and 30nm.

15. The semiconductor device of claim 13, where said semiconductor fin comprises first and second parallel semiconductor fins formed on said substrate and separated with a fin pitch between approximately 10 nm and 20 nm.

16. The semiconductor device of claim 13, where said semiconductor fin comprises first and second parallel semiconductor fins formed on said substrate and separated with a fin pitch between approximately 10 nm and 15 nm.

17. A semiconductor processing method, comprising:
forming an oxide layer on a pair of adjacent semiconductor fins supported by a substrate;
forming a semiconductor gate structure at least partially surrounding a channel portion of each semiconductor fin, said semiconductor gate structure separated from the channel portions by the oxide layer; and
forming a spacer layer on said walls of the semiconductor gate structure, comprising:
performing a selective nitridation process to deposit a nitride layer on the sidewalls of the semiconductor gate structure with a first thickness and deposit the nitride layer on the oxide layer present on source and drain portions of the semiconductor fin on opposite sides of the channel portion with a second thickness, the second thickness being less than the first thickness;
depositing an additional layer on the nitride layer and on the pair of semiconductor fins;
wherein the nitride layer and additional layer form a spacer layer having a third thickness on the semiconductor gate structure and a fourth thickness on the pair of semiconductor fins.

18. The method of claim 17, wherein the second thickness is substantially zero.

19. The method of claim 17, further comprising removing at least a portion of the additional layer from the semiconductor gate structure and the pair of semiconductor fins to form sidewall spacers on the sidewalls of the semiconductor gate structure.

20. The method of claim 17, wherein the additional layer is made of a nitride material.

21. The method of claim 17, wherein the semiconductor gate structure comprises a sacrificial gate, the method further comprising:
removing the sacrificial gate between the nitride layer formed on sidewalls of the semiconductor gate structure; and
forming a gate conductor in an area from which the sacrificial gate was removed.

22. The method of claim 17, wherein the substrate comprises one of a bulk silicon substrate or a silicon-on-insulator substrate.

23. The method of claim 17, wherein a fin pitch of the pair of adjacent semiconductor fins is between approximately 10 nm and 30 nm.

24. The method of claim 17, wherein a fin pitch of the pair of adjacent semiconductor fins is between approximately 10 nm and 20 nm.

25. The method of claim 17, wherein a fin pitch of the pair of adjacent semiconductor fins is between approximately 10 nm and 15 nm.
